(19) United States
(12) Patent Application Publication
(10) Pub. No.: US 2008/0145966 A1
(43) Pub. Date: Jun. 19, 2008

(54) METHOD FOR FABRICATION OF ORGANIC THIN-FILM TRANSISTOR

(75) Inventors: Min-Hua Yang, Taipei (TW); Meng-Che Chuang, Taipei (TW); Wei-Hsiang Lin, Taipei (TW); Yu-Hsuan Chen, Taipei (TW); Chun-Hao Hsu, Taipei (TW); Wen-Hsin Hsiao, Taipei (TW); Chih-Kung Lee, Taipei (TW); Wen-Jong Wu, Taipei (TW)

Correspondence Address: WPAT, PC;INTELLECTUAL PROPERTY ATTORNEYS, 2030 MAIN STREET, SUITE 1300, IRVINE, CA, 92614, US

(73) Assignee: NATIONAL TAIWAN UNIVERSITY, Taipei (TW)

(21) Appl. No.: 11/923,348

(22) Filed: Oct. 24, 2007

(30) Foreign Application Priority Data
Oct. 24, 2006 (TW) 095139235

(51) Int. Cl. H01L 51/40

(52) U.S. Cl. 438/99; 257/E51.005

(57) ABSTRACT

A method for fabricating organic thin-film transistors is disclosed. The method includes the steps of: providing a mold and a flexible substrate, wherein the mold comprises microstructures for defining source/drain electrode patterns on the substrate and at least an opening for feeding a solution material; forming an adhesive layer on the flexible substrate such that the mold is attached to the flexible substrate via the adhesive layer; feeding a solution material for forming source/drain electrodes via the opening of the mold and curing the solution material so as to form source/drain electrodes; removing the mold and forming a semiconductor layer on the source/drain electrodes; forming an insulator layer on the semiconductor layer and on the source/drain electrodes; forming a gate electrode on the insulator layer; and forming a protective layer for covering the organic thin-film transistor. The channel length of the thin film transistor is determined by the resolution of the microstructures of the mold.

### BACKGROUND OF THE INVENTION

1. Field of the Invention

The present invention relates generally to methods for fabrication of organic thin-film transistors, and more particularly, to a method for fabrication of organic thin-film transistors (OTFTs) or organic light emitting diodes (OLEDs) on flexible substrates.

2. Description of Related Art

According to Moore's law, the number of elements on a semiconductor chip doubles every eighteen months, which is held good in the past thirty years. For example, the DRAM in 1970 had a capacity of 1 k, capacity of the DRAM in 1995 reached 256M, and several years later the DRAM having a capacity of 1G has been developed. Meanwhile, the fabrication technique has been developed from a 10 μm process down to a 0.35 μm process in 1995 and even down to a sub 0.2 μm process. It can be seen that the micro-fabrication technique plays an important role in increasing density and decreasing cost of the semiconductor elements. Meanwhile, difficulty of the micro-fabrication technique, especially photolithography for pattern transferring, is increasing.

In simple terms, photolithography is used to integrally and precisely transfer a designed pattern to a wafer. The photolithography process involves forming a designed pattern on a photo mask, making light emitted from a light source pass through transparent region of the photo mask so as to project an image of the pattern onto a photo resist-coated wafer, and developing the exposed wafer so as to completely transfer the pattern on the photo mask to the wafer. Generally speaking, the higher the density of transistors on the wafer, the faster the operation speed and accordingly the lower the average cost. Therefore, manufacturers try to reduce the line width so as to squeeze more transistors onto a wafer. According to the Rayleigh criterion, the resolution or minimum resolvable width of the optical system is directly proportional to the wavelength (λ) of the light source and inversely proportional to the numerical aperture (NA), that is,

R=λ/NA (1)

It is so called ‘diffraction limit’. According to the equation, the shorter the wavelength of the exposure light source is, the smaller the line width becomes. With the electronic elements advance from the micro-scale to nano-scale level, extreme ultraviolet, X-ray, electron beam, ion beam and so on have been tried to be used in photolithography. However, as the light sources and peripheral equipments are quite expensive and fabrication speed is rather slow, mass production is quite difficult to be realized.

Accordingly, another research direction is to go back to the traditional printing method. For example, the nanoimprint lithography (NIL) is akin to a traditional imprint concept, of which a mold having a nanopattern is pressed to a substrate coated with polymer resist by a mechanical force so as to transfer the nanopattern to the substrate. The resolution of the process corresponds to the critical size of the pattern on the mold. Further, only one mold needs to be fabricated, through which pattern transferring can be performed quickly and repeated many times, thus facilitating the realization of mass production. Furthermore, as the print process is an additive process, waste of material can be reduced. Moreover, when the nanoimprint lithography is applied to large area pattern transferring, the equipment cost of the nanoimprint lithography is relatively lower than that of the photolithography. Therefore, in 2003, the ITRS (International Technology Roadmap for Semiconductors) added the imprint lithography (IL) as candidates for next-generation lithography. The nanoimprint lithography is expected to be applied to the 32 nm process in 2010.

The nanoimprint lithography is classified into three mainstream techniques:

1. hot embossing nanoimprint lithography (HE-NIL), wherein a thermoplastic polymer material such as PMMA is used and a large area nanostructure transferring is realized at high temperature and high pressure, but thermal expansion of the surface of the nanostructure at high temperature and high pressure can result in such problems as size error;

2. UV-cured nanoimprint lithography (UV-NIL), wherein a photosensitive polymer material instead of a theremoplastic polymer material is used and a UV-transparent mold such as quartz is used for pattern transferring, allowing the photosensitive polymer material to be exposed by ultraviolet (UV) light and cured according to the nanostructure of the mold, but as coating of the photosensitive polymer does not experience heating, micro air bubbles contained in the photosensitive polymer cannot be efficiently dissipated, also, the photo resist cannot be fabricated by spin coating in a large area due to its viscosity feature, instead, the photo resist can only be fabricated through a nano-dispensing process; and

3. soft lithography, which is divided into five categories according to different fabrication principles: (1) replica molding (REM): a liquid prepolymer such as PDMS is introduced into a mold, and the mold is then removed after the liquid prepolymer is cured to obtain a corresponding microstructure; (2) microtransfer molding (μTM): a prepolymer such as UV-PU photo resist is introduced into a PDMS mold until the mold is completely filled, and the superfluous prepolymer is then removed by a scraper or nitrogen gas to allow the PDMS mold filled with the prepolymer to attach to a substrate; the prepolymer in the PDMS mold is then exposed and cured by heating to obtain the desired microstructure after the PDMS mold is removed; (3) micromolding in capillaries (MIMIC): a PDMS mold is disposed on a substrate and a prepolymer of low viscosity is fed into grooves formed on the PDMS mold via an opening of the PDMS mold by capillary effect; after cured, the prepolymer filled in the grooves form the microstructure on the substrate subsequent to the removal of the PDMS mold; (4) solvent-assisted micromolding (SAMIM): the substrate precoated with a polymer layer is brought into contact with a solvent applied to a PDMS mold, such that the polymer layer can be dissolved by the solvent so as to form a desired microstructure on the substrate corresponding to the preformed pattern on the mold; and (5) microcontact printing (μCP): a flexible PDMS mold coated with a self-assembly monomer (SAM) is brought into contact with a substrate plated with a metal thin film and the PDMS is then slightly pressed toward the substrate; it allows the self-assembly monomer on the protruded portion of the surface of the PDMS mold to be transferred to the metal thin film to thereby cause the self-assembly monomer transferred to the metal thin film to be bonded with the metal thin film. As a result, a desired microstructure is formed on the metal thin film on the substrate.

Although the above three mainstream techniques are different in processes, they all originate from the concept of mold-aided imprint and can be used to realize large area printing or pattern transferring and are applicable in mass production.

However, the above mentioned conventional methods or processes still have problems to be solved, such as deformation caused by heat and pressure during processing, increasing need of flexible polymer material for fabricating the PDMS mold or the higher cost for the PDMS mold.

Another need for forming desired microstructures on a substrate results from the development of the flexible display technology. Flexible display technologies enable design of displaying devices that is no longer limited to planar appearance and instead thinner and more reliable. The flexible display technologies are thus applicable to portable products such as mobile phones, PDAs and notebook computers. On the other hand, roll-to-roll manufacturing is possible for the flexible substrates required for flexible displays, through which the manufacturing cost of the flexible displays can be significantly reduced. To make the roll-to-roll manufacturing for the flexible displays possible, processes for fabricating thin-film transistors are required to be performed at low temperature so as to prevent the flexible substrate employed for the flexible display from being damaged due to its poor heat resistance; and have alternative methods for replacing those such as vacuum and exposure that are expensive and limited in the fabrication area.

The above two requirements can be met by using organic semiconductor materials. The organic semiconductor materials can be divided into two categories according to molecular structures: small molecule organic semiconductor materials and polymer organic semiconductor materials. The most commonly used small molecule organic semiconductor material is pentacene, which can be directly vapor deposited onto plastic substrates at temperature of 80-100° C. Components having a mobility of 0.3-2.2 cm²/V-sec have been successfully fabricated. However, problems existing in the fabrication process such as the use of expensive vacuum equipment and limited size of the transistor array need to be solved.

Different from small molecule organic semiconductor materials, polymer organic semiconductor materials are soluble in some organic solvents, and accordingly can be fabricated at a liquid state. The polymer organic semiconductor materials currently available are dihexyl-hexithiophene (DH6T), dihexylanthradithiophene (DHADT), poly(3-hexythiophene) (P3HT), poly(9,9-dioctylfluorene-co-bithiophene) (F8T2), and poly[5,5′-bis(3-dodecyl-2-thienyl)-2,2′-bithiophene] (PQT-12) etc. Among them, which P3HT and PQT-12 are conjugated polymers with high mobility such that they are stable in the ambient air. As the solution-processing approach is rather simple and low at cost, it is suitable to be applied in fabricating flexible displays.

Currently, inkjet printing is commonly used in fabricating organic thin-film transistors on flexible substrates. However, inkjet equipment is costly in large area manufacturing and mass production.

### SUMMARY OF THE INVENTION

In order to solve the above problems, the present invention proposes a method for fabrication of organic thin-film transistors on a substrate.

The method for fabrication of organic thin-film transistors according to the present invention at least comprises the steps of: providing a mold and a substrate, wherein the mold has a plurality of microstructures for defining a source/drain electrode pattern on the substrate and at least an opening for feeding a solution material into the microstructures of the mold; closely attaching the mold to the substrate via a surface of the mold on which the microstructures are formed, allowing the attachment of the mold to the substrate to be achieved by an adhesive force provided by an adhesive layer interposed between the mold and substrate, or a mechanical force provided by thermal-press; feeding the solution material into the microstructures of the mold through the opening of the mold; and curing the solution material, followed by removing the mold so as to form on the substrate the desired source/drain electrode pattern corresponding to the microstructures of the mold.

Microstructures of high ratio of depth to width and low surface roughness can be formed on the mold via the LIGA technique, the NEMS technique, the metal fine processing technique and so on. The resolution of the microstructures is about several micrometers. The microstructures of the mold are capable of being transferred to a substrate at a ratio of 1:1 through the micro-molding technique. Further, if the pattern to be defined on the substrate has one or more closed channels or separate regions, additional microstructures can be formed on another surface of the mold opposite to the one where the microstructures are formed for connecting the closed channels or the separate regions, thereby decreasing the number of the openings required for feeding the solution material.

The openings of the mold for feeding the solution material can be specifically processed by a special solution or surface material so as to accelerate the feeding speed of the solution material. In addition, the feeding speed can be accelerated at a vacuum environment.

The method of the present invention requires the mold to be closely attached to the substrate in order to effectively form the source/drain electrode pattern on the substrate via the microstructures of the mold. It thus can be achieved, for example, an adhesive layer pre-coated on the substrate, or an adhesive material fed into the microstructures through the opening of the mold with a predetermined amount sufficient to adhere the mold to the substrate. Alternatively, the microstructures on the mold can be slightly pressed into the substrate through thermal pressing. Accordingly, the method according to the present invention leaves no residual material required to be processed. Further, the method of the present invention can directly feed a solution material for forming the source/drain electrodes, or a semiconductor solution material or an insulation solution material for forming thin-film transistors on the substrate. Therefore, the method of the present invention is subject to an one-time process.

The solution material can be a semiconductor solution material, a conductive solution material, an insulation solution material or a photoresist solution material. The semiconductor solution material is usually a soluble polymer organic semiconductor material such as dihexyl-hexithiophene (DH6T), dihexylanthradithiophene (DHADT), poly(3-hexythiophene) (P3HT), poly(9,9-dioctylfluorene-co-bithiophene) (F8T2) and so on. Although the organic semiconductor materials with small molecules also have desired feature performance, they are mostly not soluble in solvent. Nevertheless, to be applied to the solution process, the organic semiconductor materials with small molecules can become soluble by being synthesized with small molecule soluble precursor material such as pentacene-precursor which is most commonly used. The insulation solution material can be, for instance, polyimide (PI), polyvinylphenol (PVP), poly-methyl methacrylate (PMMA) and polyvinylalcohol (PVA). The insulation materials mainly comprise polymers, which have good insulation property and an extremely low leakage current when a voltage is applied. The conductive solution material comprises such materials as conductive polymers and conductive inorganic materials. The suitable conductive polymers can be, for example, poly(3,4-ethylenedioxythiophene)/poly(styrene sulfonic acid) (PEDOT/PSS), polypyrrole (PPy), polyaniline and poly(phenylene vinylene) (PPV), and the conductive inorganic materials can be, for instance, nanogold solution and nanosilver solution prepared via nano-technologies.

According to the method proposed by the present invention, as it is subject to a solution process without heating, organic thin-film transistors can thus be formed on flexible substrates.

### BRIEF DESCRIPTION OF DRAWINGS

FIGS. 1A to 1H are diagrams showing the steps of the method for fabricating an organic thin-film transistor according to the first embodiment of the present invention;

FIGS. 2A to 2F are diagrams showing the steps of the method for fabricating an organic thin-film transistor according to the second embodiment of the present invention;

FIGS. 3A to 3G are diagrams showing the steps of the method for fabricating an organic thin-film transistor according to the third embodiment of the present invention;

FIGS. 4A to 4G are diagrams showing the steps of the method for fabricating an organic thin-film transistor according to the fourth embodiment of the present invention;

FIGS. 5A to 5H are diagrams showing the steps of the method for fabricating an organic thin-film transistor according to the fifth embodiment of the present invention;

FIGS. 6A to 6G are diagrams showing the steps of the method for fabricating an organic thin-film transistor according to the sixth embodiment of the present invention; and

FIGS. 7A to 7H are diagrams showing the steps of the method for fabricating an organic thin-film transistor according to the seventh embodiment of the present invention.

### DETAILED DESCRIPTION OF PREFERRED EMBODIMENTS

The following illustrative embodiments are provided to illustrate the disclosure of the present invention, these and other advantages and effects can be apparent to those skilled in the art after reading the disclosure of this specification.

### First Embodiment

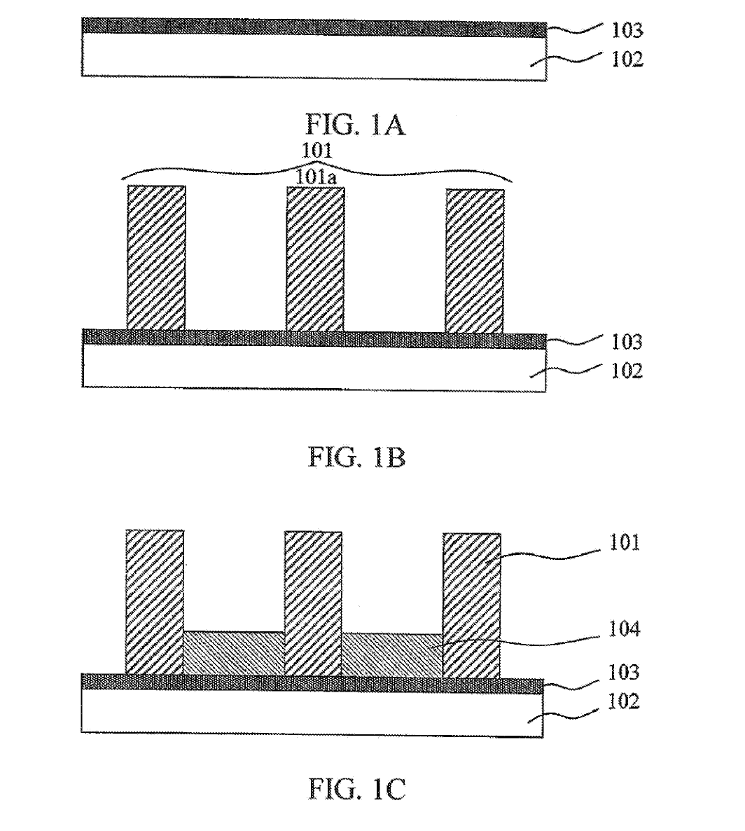

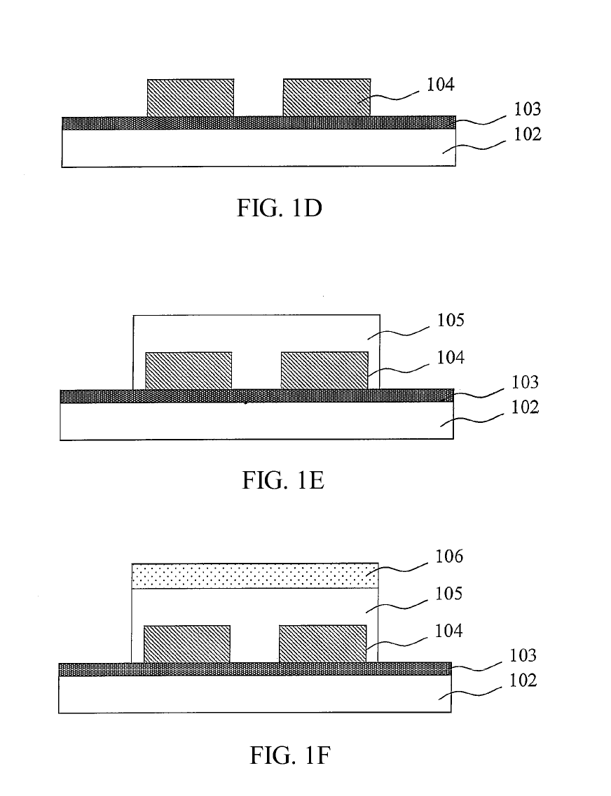

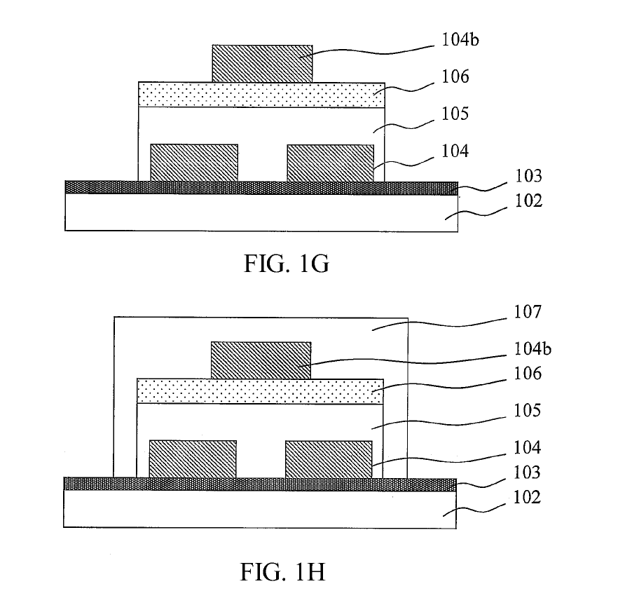

FIGS. 1A to 1H are diagrams showing the steps of the method for fabricating an organic thin-film transistor according to the first embodiment of the present invention.

As shown in FIGS. 1A and 1B, a flexible metal or plastic substrate 102 is provided, which has an adhesive layer 103 formed thereon by spin coating or screen printing. Then, a metal or plastic mold 101 is attached to the flexible substrate 102 via the adhesive layer 103. The mold 101 can be fabricated through EDM technique or NEMS technique, and the mold 101 has a first primary face formed with microstructures 101a for defining source/drain electrode pattern on the substrate 102 and a second primary face formed with an opening (not shown) for feeding a solution material.

As shown in FIGS. 1C and 1D, a conductive polymer solution or oxidation-reduction metal solution material for forming the source/drain electrodes is fed via the opening of the mold 101. After the material is cured, the mold 101 is removed from the adhesive layer 103 to allow the cured solution material to form the source/drain electrodes 104 of an organic thin-film transistor on the substrate 102.

As shown in FIGS. 1E to 1F, an organic polymer semiconductor layer 105 is formed on the source/drain electrodes 104 and the adhesive layer 103, and an organic polymer insulation layer 106 is further formed on the semiconductor layer 105.

As shown in FIGS. 1G and 1H, a gate electrode 104b is formed on the insulation layer 106. The gate electrode 104b can be made of one of a conductive polymer solution and an oxidation-reduction metal solution. Further, a protective layer 107 is optionally formed to cover the organic thin-film structure formed by the source/drain electrodes 104, the semiconductor layer 105, the insulation layer 106 and the gate electrode 104b.

The present embodiment features in defining position of the source/drain electrodes 104 via the microstructures of the mold 101 as shown in FIGS. 1B to 1D, which determines the channel size of the organic thin-film transistor and further influences performance of the organic thin-film transistor.

### Second Embodiment

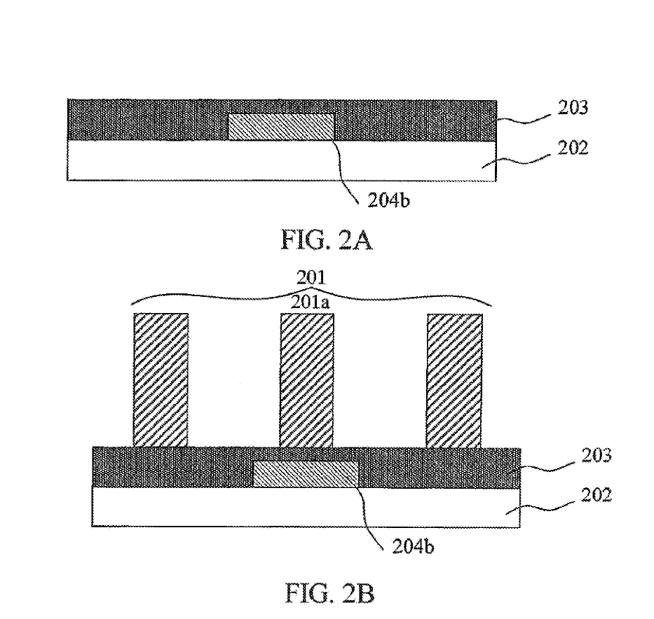

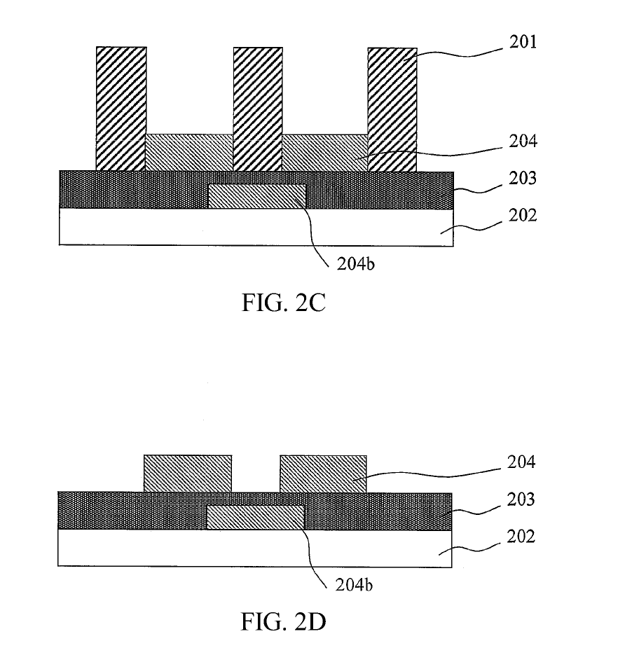

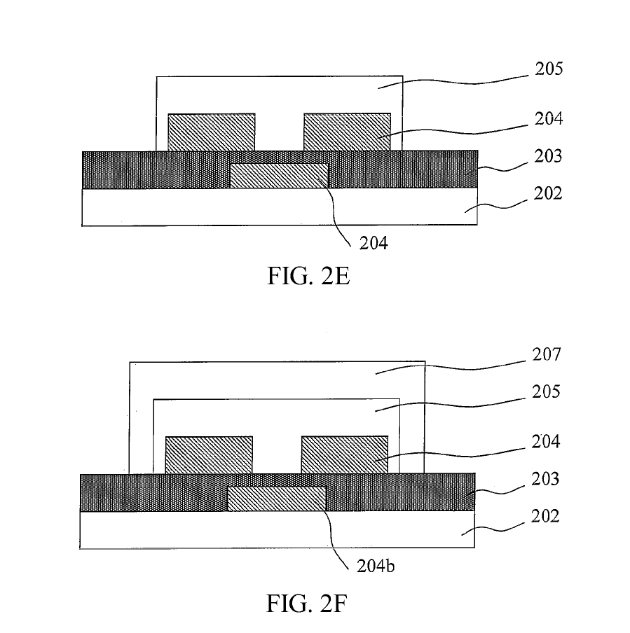

FIGS. 2A to 2F are diagrams showing the steps of the method for fabricating an organic thin-film transistor according to the second embodiment of the present invention.

As shown in FIGS. 2A and 2B, a flexible substrate 202 and a mold 201 are provided, wherein the mold 201 has a first primary face formed with microstructures 201a for defining source/drain electrode pattern on the substrate 202 and a second primary face formed with an opening (not shown) for feeding a solution material. A gate electrode 204b is formed on the flexible substrate 202. An adhesive layer 203 is formed on the flexible substrate 202 so as to attach the mold 201 to the flexible substrate 202. The adhesive layer 203 also functions as an insulation layer of an organic thin-film transistor.

As shown in FIGS. 2C and 2D, a solution material for forming the source/drain electrodes is fed via the opening of the mold 201 and cured on the adhesive layer 203. Thereafter, the mold 201 is removed from the adhesive layer 203 to allow the solution material to form the source/drain electrodes 204 of an organic thin-film transistor on the substrate 202.

As shown in FIGS. 2E to 2F, a semiconductor layer 205 and a protective layer 207 are formed respectively on the source/drain electrodes 204 and the adhesive layer 203.

### Third Embodiment

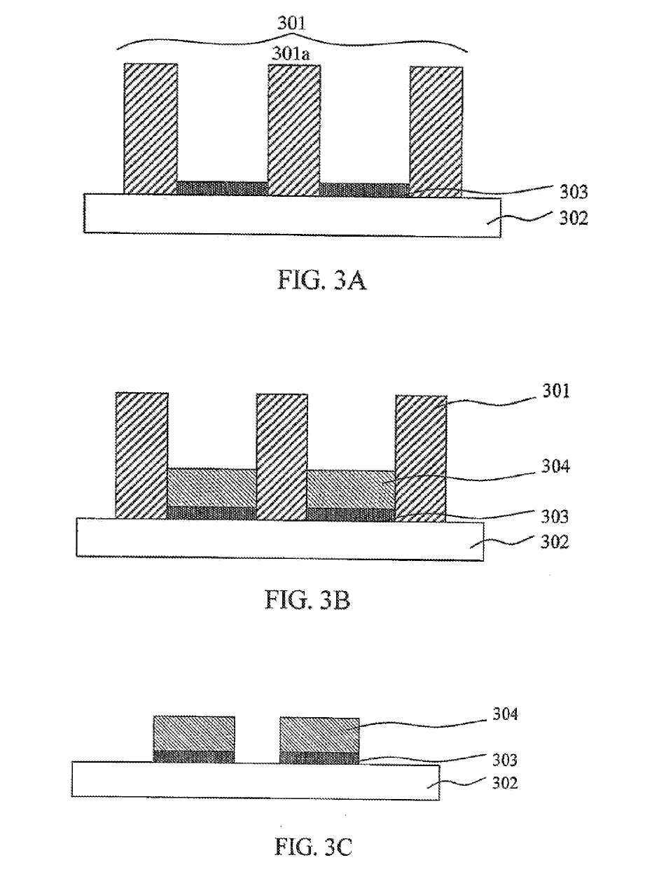

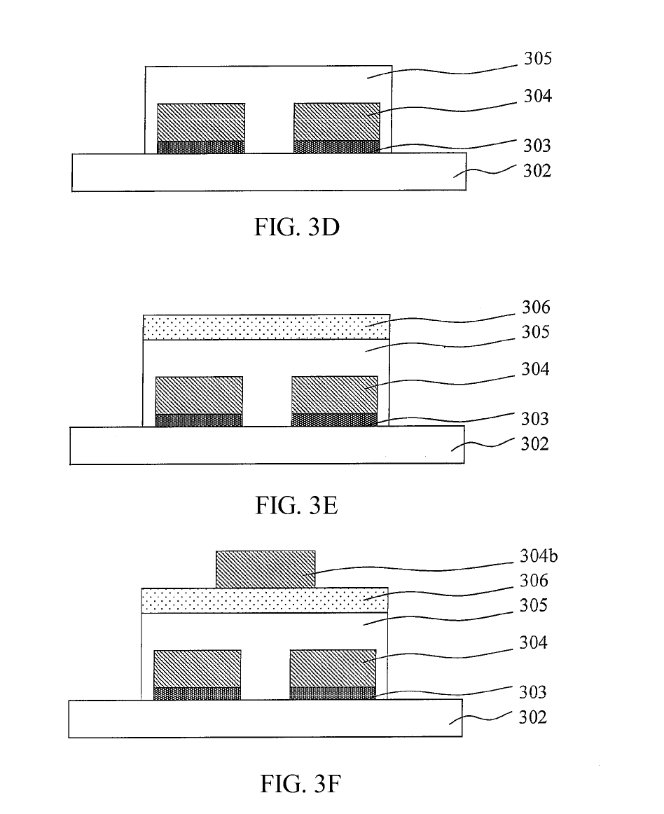

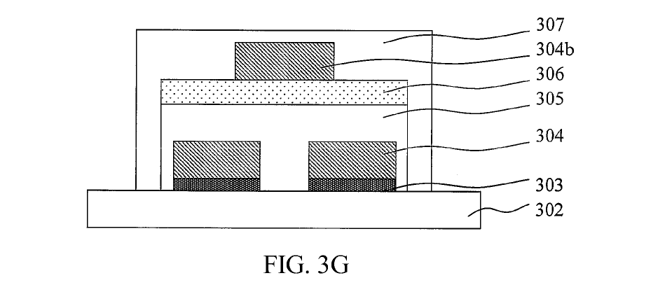

FIGS. 3A to 3G are diagrams showing the steps of the method for fabricating an organic thin-film transistor according to the third embodiment of the present invention.

As shown in FIGS. 3A and 3B, a flexible substrate 302 is provided and a mold 301 is fixed to the flexible substrate 302, wherein the mold 301 has a first primary face formed with microstructures 301a for defining source/drain electrode pattern on the substrate 302 and a second primary face formed with an opening (not shown) for feeding a solution material. An adhesive material is fed via the opening of the mold 301 so as to form an adhesive layer 303, thereby closely attaching the mold 301 to the flexible substrate 302. Thereafter, a solution material for forming the source/drain electrodes is fed via the opening of the mold 301 and cured.

As shown in FIGS. 3C to 3G, the mold 301 is removed to allow the cured solution material to form the source/drain solution electrodes 304 of an organic thin-film transistor on the substrate 302. Thereafter, a semiconductor layer 305, an insulation layer 306, a gate electrode 304b and a protective layer 307 are formed respectively on the source/drain electrodes 304.

### Fourth Embodiment

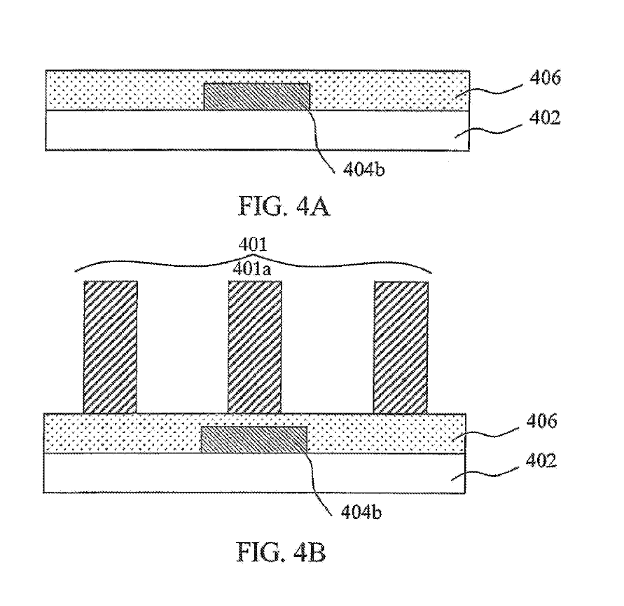

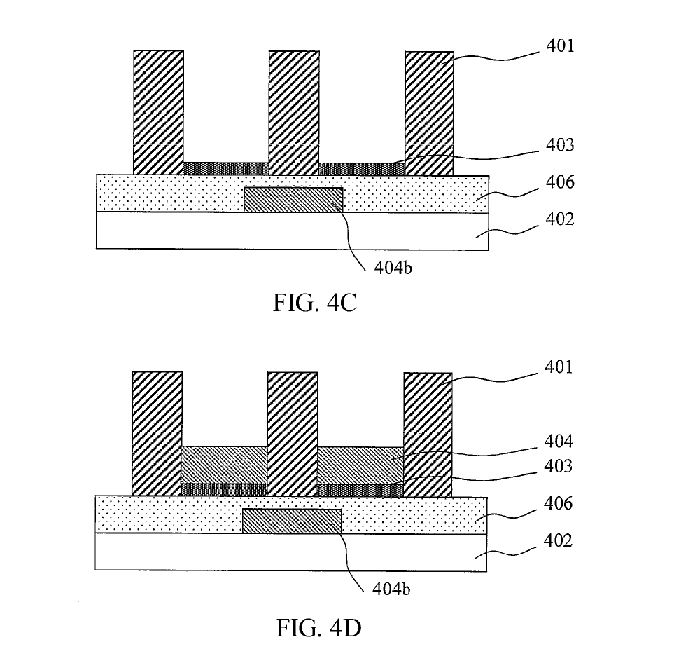

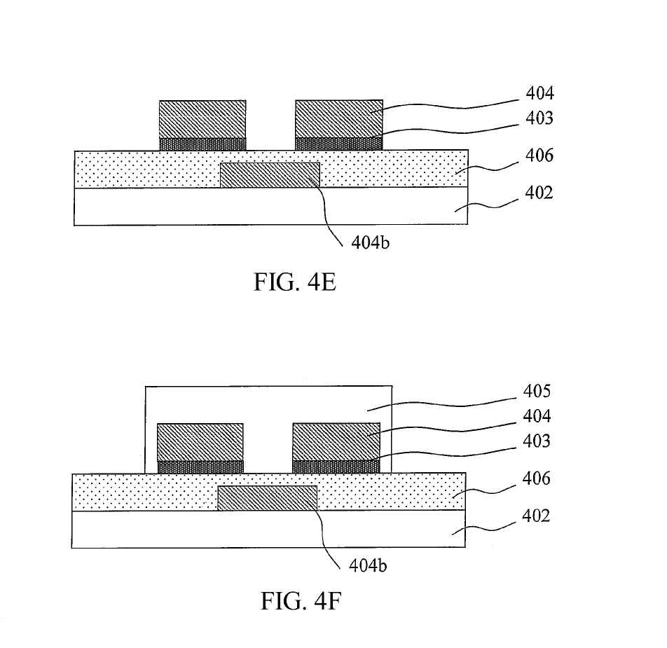

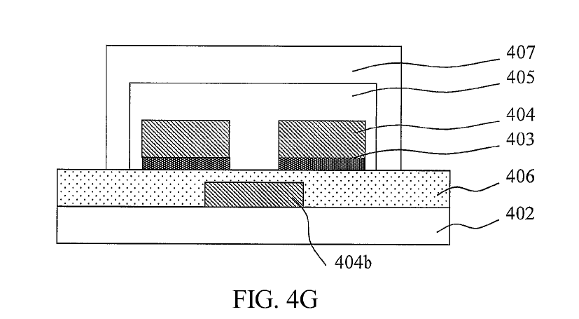

FIGS. 4A to 4G are diagrams showing the steps of the method for fabricating an organic thin-film transistor according to the fourth embodiment of the present invention.

As shown in FIGS. 4A to 4D, a flexible substrate 402 is provided, and a gate electrode 404b and an insulation layer 406 are formed on the flexible substrate 402. A mold 401 is fixed on the insulation layer 406, wherein the mold 401 has a first primary face formed with microstructures 401a for defining source/drain electrode pattern and a second primary face formed with an opening (not shown) for feeding a solution material. An adhesive material is fed via the opening of the mold 401 so as to form an adhesive layer 403, thereby closely attaching the mold 401 to the flexible substrate 402. Thereafter, a solution material for forming the source/drain electrodes is fed via the opening of the mold 401 and cured.

As shown in FIGS. 4E to 4G, the mold 401 is removed to allow the solution material to form the source/drain electrodes 404 of an organic thin-film transistor. Thereafter, a semiconductor layer 405 and a protective layer 407 are formed respectively on the source/drain electrodes 404.

### Fifth Embodiment

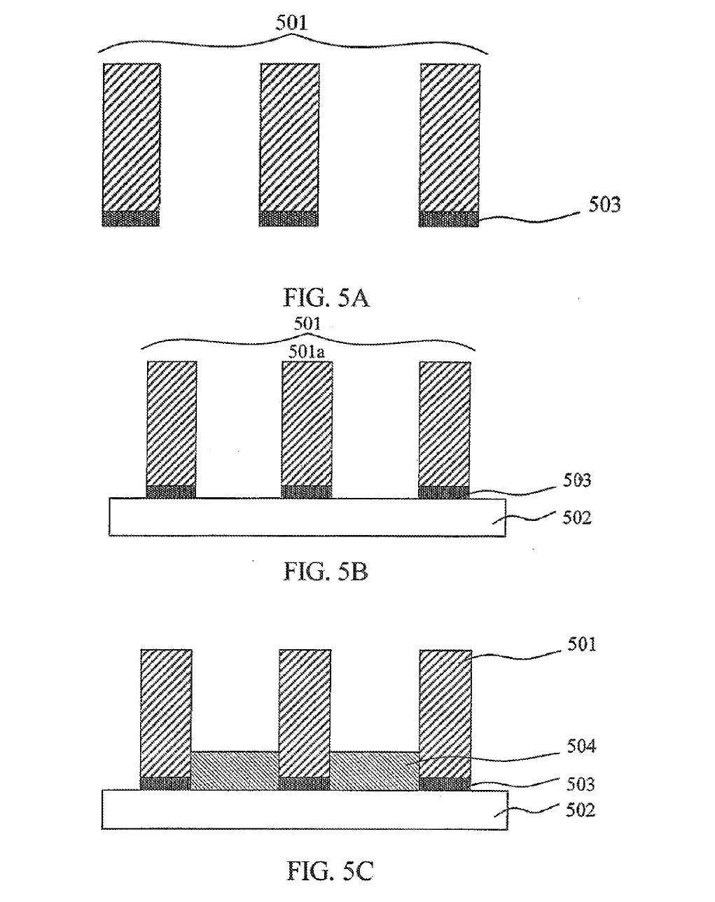

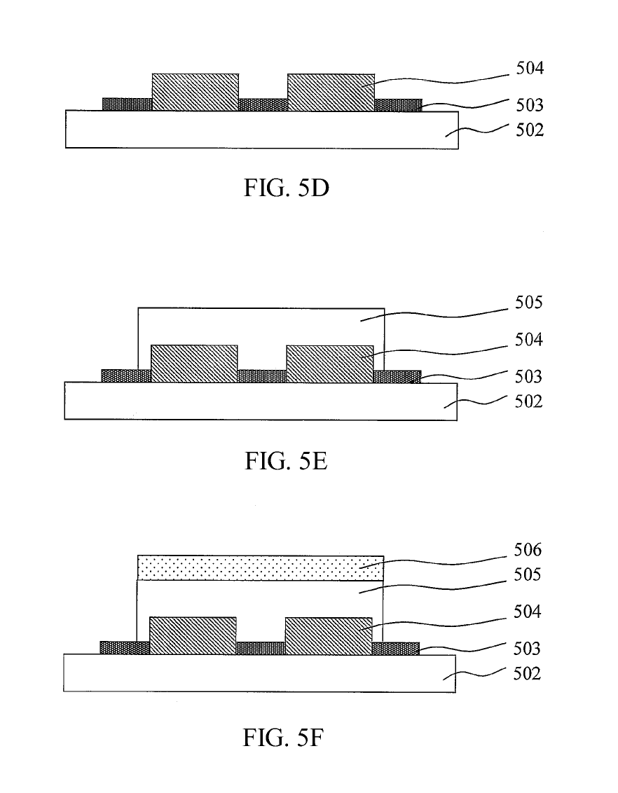

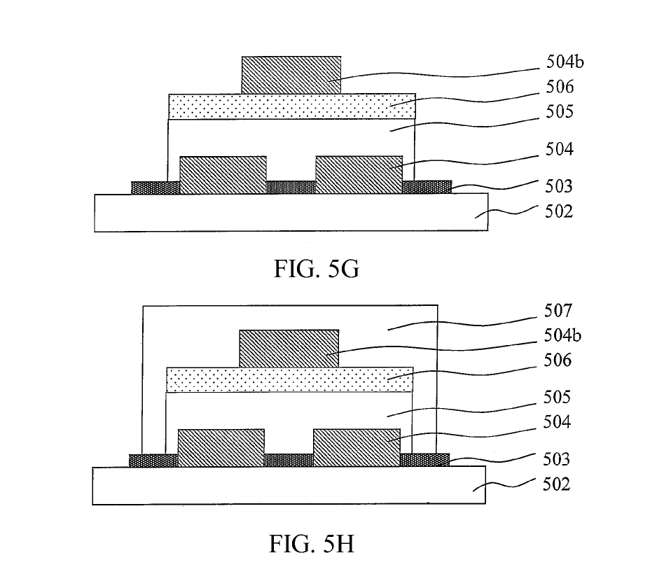

FIGS. 5A to 5H are diagrams showing the steps of the method for fabricating an organic thin-film transistor according to the fifth embodiment of the present invention.

As shown in FIGS. 5A to 5C, a flexible substrate 502 and a mold 501 are provided, wherein the mold 501 has a first primary face formed with microstructures 501a for defining source/drain electrode pattern and a second primary face formed with an opening (not shown) for feeding a solution material. The microstructures 501a of the mold 501 are coated with an adhesive layer 503, through which the mold 501 is closely attached to the flexible substrate 502. Thereafter, a solution material for forming source/drain electrodes is fed via the opening of the mold 501 and cured.

As shown in FIGS. 5D to 5H, the mold 501 is removed to allow the cured solution material to form the source/drain electrodes 504 of an organic thin-film transistor. Thereafter, a semiconductor layer 505, an insulator layer 506, a gate electrode 504b and a protective layer 507 are formed respectively on the source/drain electrodes 504.

### Sixth Embodiment

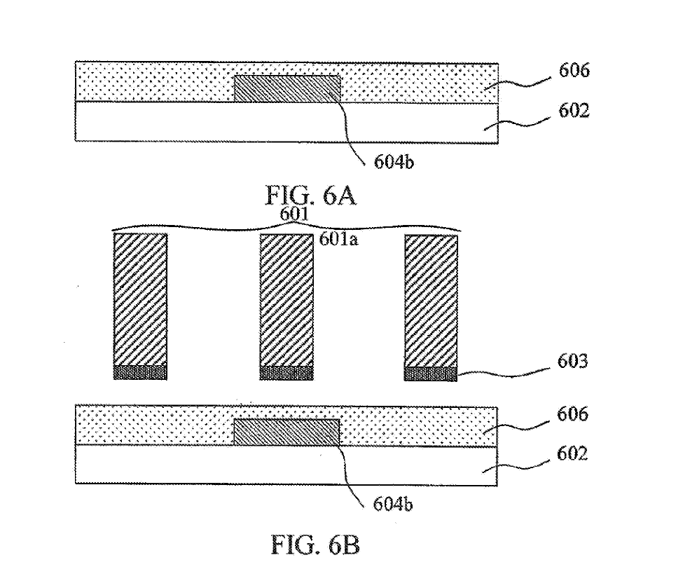

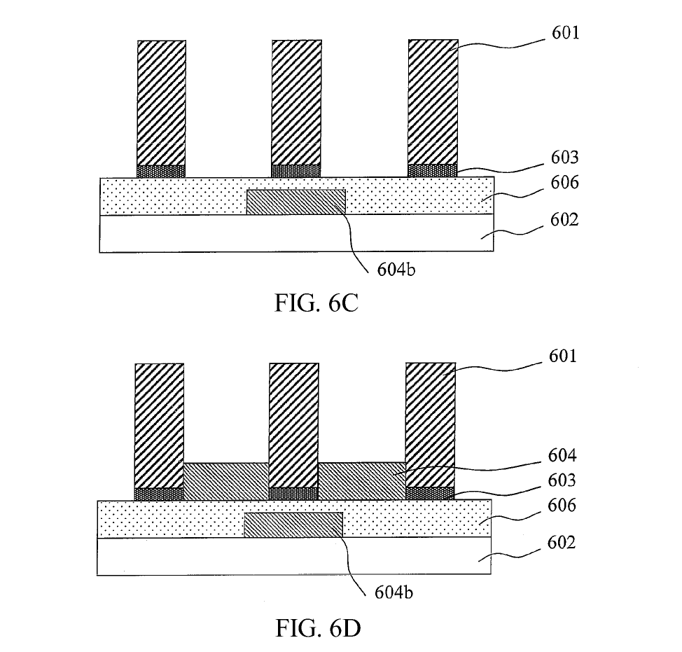

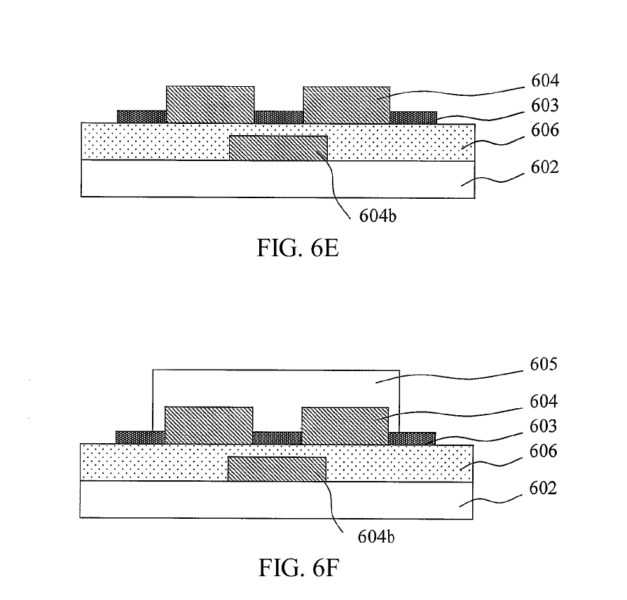

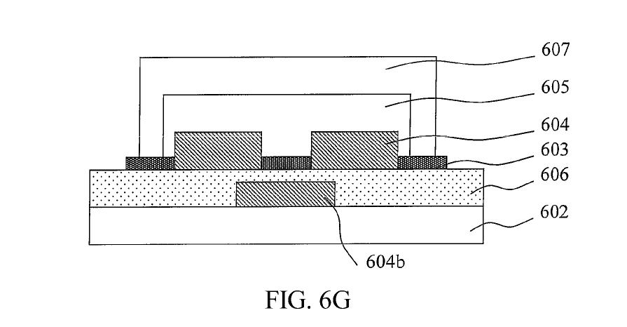

FIGS. 6A to 6G are diagrams showing the steps of the method for fabricating an organic thin-film transistor according to the sixth embodiment of the present invention.

As shown in FIGS. 6A to 6D, a flexible substrate 602 is provided, and a gate electrode 604b and an insulator layer 606 are formed on the flexible substrate 602. A mold 601 has a first primary face formed with microstructures 601a for defining source/drain electrode pattern and a second primary face formed with an opening (not shown) for feeding a solution material. The microstructures 601a of the mold 601 are coated with an adhesive layer 603, through which the mold 601 is closely attached to the flexible substrate 602. Thereafter, a solution material for forming source/drain electrodes is fed via the opening of the mold 601 and cured.

As shown in FIGS. 6E to 6G, the mold 601 is removed to allow the cured solution material to form source/drain electrodes 604 of an organic thin-film transistor. Thereafter, a semiconductor layer 605 and a protective layer 607 are formed respectively on the source/drain electrodes 604. Materials and fabrication method for forming the organic thin-film transistor in the present embodiment are same as those of the first embodiment.

### Seventh Embodiment

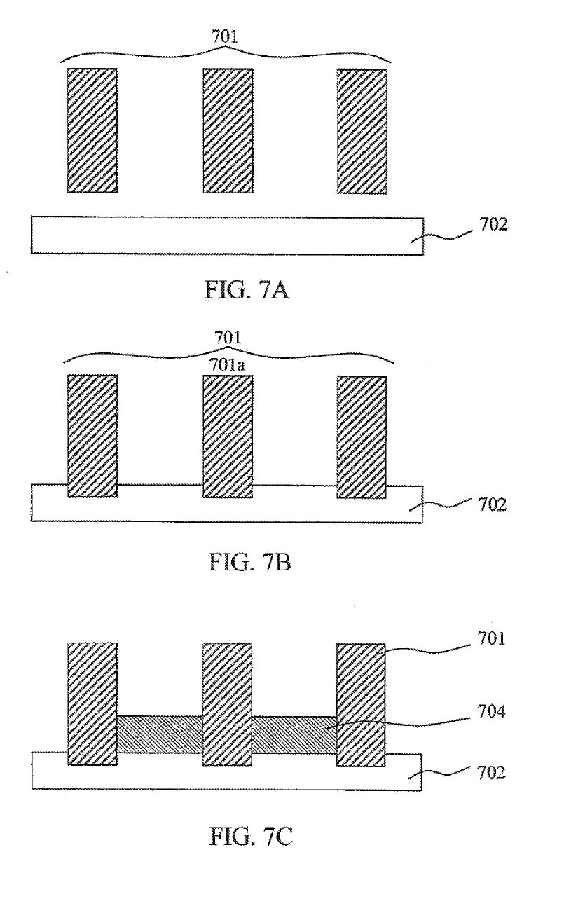

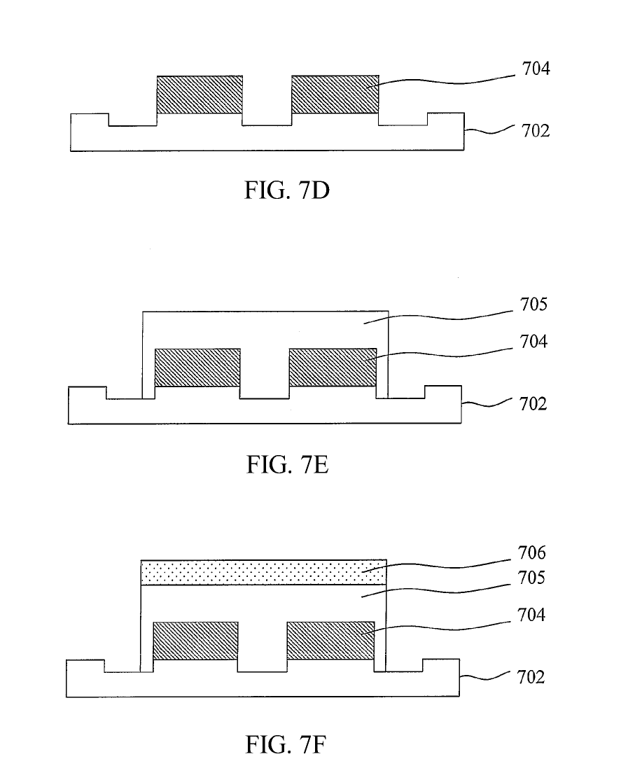

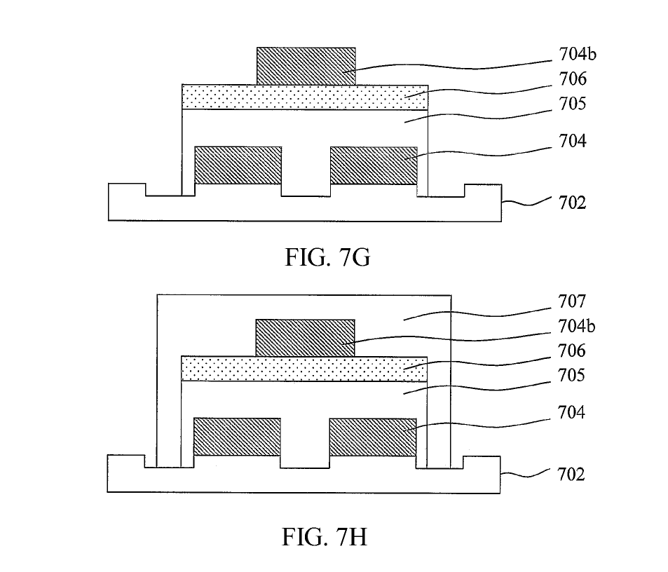

FIGS. 7A to 7H are diagrams showing the steps of the method for fabricating an organic thin-film transistor according to the seventh embodiment of the present invention.

As shown in FIGS. 7A to 7C, a plastic substrate 702 and a mold 701 are provided. The mold 701 has a first primary face formed with microstructures 701a for defining source/drain electrode pattern and a second primary face formed with an opening (not shown) for feeding a solution material. The mold 701 is pressed toward the plastic substrate 702 and closely attached to the plastic substrate 702. Thereafter, a solution material for forming source/drain electrodes is fed via the opening of the mold 701 and cured.

As shown in FIGS. 7D to 7H, the mold 701 is removed to allow the cured solution material to form source/drain electrodes 704 of an organic thin-film transistor. Thereafter, a semiconductor layer 705, an insulation layer 706, a gate electrode 704b and a protective layer 707 are formed respectively on the source/drain electrodes 704.

Therefore, the method for fabricating the organic thin-film transistor according to the present invention is direct to defining position of electrodes and size of transistor channel via a mold.

The above-described descriptions of the detailed embodiments are only to illustrate the preferred implementation according to the present invention, and it is not to limit the scope of the present invention, Accordingly, all modifications and variations completed by those with ordinary skill in the art should fall within the scope of present invention defined by the appended claims.

What is claimed is:

1. A method for fabricating an organic thin-film transistor, comprising the steps of:
providing a mold and a substrate, wherein the mold has a plurality of microstructures for defining a source/drain electrode pattern on the substrate and at least an opening for feeding a solution material;
attaching the mold to the substrate;
feeding the solution material through the at least an opening of the mold;
curing the solution material and then removing the mold, allowing the cured solution material to form source/drain electrodes on the substrate;
forming a semiconductor layer on the source/drain electrodes and at least a portion of the substrate;
forming an insulation layer on the semiconductor layer; and
forming at least a gate electrode on the insulation layer.

2. The method of claim 1, wherein the substrate is a flexible substrate selected from the group consisting of a glass substrate, a metal substrate and a plastic substrate.

3. The method of claim 1, wherein the microstructure of the mold is of resolution between 0.2 and 2 μm.

4. The method of claim 1, wherein the mold is made of a material selected from the group consisting of a metal material, a non-metal material, a plastic material and a silicon material.

5. The method of claim 1, wherein the microstructures of the mold is formed by a method selected from the group consisting of a metal fine processing process, an LIGA process, a NEMS process, an FIB process and an excimer laser micro-processing technique.

6. The method of claim 1, wherein the mold is attached to the substrate by an adhesive layer formed on the substrate, wherein the adhesive layer is formed by a method selected from the group consisting of spin coating, blade coating and screen printing.

7. The method of claim 1, wherein the mold is mounted on an insulation layer formed on the substrate, allowing the mold to be fixedly attached to the substrate by an adhesive material applied on the microstructures through the opening of the mold.

8. The method of claim 1, wherein the solution material is selected from the group consisting of an organic conductive material solution, an oxidation-reduction metal material solution, a nano conductive material solution and an inorganic conductive dispersion solution.

9. The method of claim 1, wherein the semiconductor layer is made of a material selected from the group consisting of an organic small molecule soluble material, an organic polymer soluble material, a nano semiconductor material and an inorganic semiconductor dispersion material, and wherein the semiconductor layer is formed by a method selected from the consisting of coating, printing, inkjet printing, microcontact imprinting and soft lithography.

10. The method of claim 1, wherein the insulation layer is formed by a method selected from the group consisting of coating, screen printing, inkjet printing, blade coating, microcontact imprinting and soft lithography.

11. The method of claim 1, wherein the gate electrode is made of a material selected from the group consisting of an organic conductive material solution, an oxidation-reduction metal material solution, a nano conductive material solution and an inorganic conductive dispersion solution, and wherein the gate electrode is formed by a method selected from the group consisting of coating, printing, inkjet printing, microcontact imprinting and soft lithography.

12. The method of claim 1, further comprising forming a protective layer on the organic thin-film transistor by a method selected from the group consisting of coating, printing and inkjet printing.

13. A method for fabricating an organic thin-film transistor, comprising the steps of:
providing a mold and a substrate, wherein the mold has a plurality of microstructures for defining source/drain electrode pattern on the substrate and at least an opening for feeding a solution material;
forming at least a gate electrode on the substrate;
forming an insulation layer on the at least a gate electrode and the substrate;
attaching the mold to the insulation layer;
feeding the solution material through the at least an opening of the mold;
curing the conductive solution material and then removing the mold, allowing the cured solution material to form source/drain electrodes on the insulation layer; and
forming a semiconductor layer on the source/drain electrodes and the insulation layer.

14. A method for defining pattern on a substrate, comprising the steps of:
providing a mold and a substrate, wherein the mold has a first surface formed with a plurality of microstructures for defining patterns on the substrate and a second surface formed with at least an opening for feeding a solution material;
attaching the first surface of the mold to the substrate;
feeding a solution material into the microstructures through the at least an opening of the curing the solution material; and
removing the mold so as to form the patterns on the substrate.

15. The method of claim 14, wherein the second surface of the mold comprises another microstructures for being connected to a closed channel on the first surface.

16. The method of claim 14, wherein the first surface of the mold is attached to the substrate by an adhesive layer.

17. The method of claim 14, wherein the substrate is one of a glass substrate and a metal substrate.

18. The method of claim 14, wherein the substrate is a plastic substrate.

19. The method of claim 18, wherein the mold is attached to the plastic substrate by an imprinting process.

20. The method of claim 14, wherein the mold is made of one of a metal material, a non-metal material, a plastic material and a silicon material.

21. The method of claim 14, wherein the mold is formed by a method selected from the group consisting of a metal fine processing process, an LIGA process, a NEMS process, an FIB process and an excimer laser micro-processing process, and the microstructures of the mold is of a resolution between 0.2 and 20 μm.

22. The method of claim 14, wherein the solution material is a conductive solution material selected from the group consisting of an organic conductive material, an oxidation-reduction metal material, a nano conductive material and an inorganic conductive dispersion material.

23. The method of claim 14, wherein the solution material is a semiconductor material selected from the group consisting of an organic small molecule soluble material, an organic polymer soluble material, a nano semiconductor material and an inorganic semiconductor dispersion material.

24. The method of claim 14, wherein the solution material is one of an insulation solution material and a photoresist.

25. The method of claim 14, wherein an interval between the patterns is no more than 100 μm.

26-47. (canceled)
